(19) United States
(12) Patent Application Publication
(10) Pub. No.: US 2017/0345925 A1
(43) Pub. Date: Nov. 30, 2017

(54) SEMICONDUCTOR DEVICE AND ITS MANUFACTURING METHOD

(71) Applicant: Renesas Electronics Corporation, Tokyo (JP)

(72) Inventor: Toshiyuki SYO, Hitachinaka-shi (JP)

(21) Appl. No.: 15/480,095

(22) Filed: Apr. 5, 2017

(30) Foreign Application Priority Data
May 24, 2016 (JP) 2016-103080

(51) Int. Cl. H01L 29/78; H01L 29/40; H01L 21/3213; H01L 21/02; H01L 21/311; H01L 29/66; H01L 29/06

(52) U.S. Cl. CPC H01L 29/7816; H01L 29/66681; H01L 29/408; H01L 29/402; H01L 29/0653; H01L 21/02164; H01L 21/31116; H01L 21/02274; H01L 21/02216; H01L 21/32137

(57) ABSTRACT

A semiconductor device includes a field effect transistor (LDMOSFET) having a field relaxing part. This field relaxing part has a trench, a charge capture film, and an insulating film. The trench is formed in a semiconductor substrate. The charge capture film is formed only on the side wall of the trench. The insulating film is formed over the charge capture film, and is embedded in the trench.

### CROSS-REFERENCE TO RELATED APPLICATIONS

The disclosure of Japanese Patent Application No. 2016-103080 filed on May 24, 2016 including the specification, drawings and abstract is incorporated herein by reference in its entirety.

The present invention relates to a semiconductor device and its manufacturing technique, and relates to a semiconductor device including, for example, a field effect transistor having a field relaxing part for ensuring a withstand voltage and an effective technique applied to its manufacturing technique.

### BACKGROUND

Japanese Unexamined Patent Application Publication No. 2000-294747 discloses a technique for forming a nitride layer through an oxide layer, on a side wall of the upper part of a trench, with a trench capacity of a DRAM.

Japanese Unexamined Patent Application Publication No. 2009-278100 discloses a technique regarding a field effect transistor having a field relaxing part having a trench structure.

### SUMMARY

For example, according to the examination by the present inventors, it is understood that a field concentration region is generated in a semiconductor region in the vicinity of the bottom corner part of the field relaxing part, in a field effect transistor having the field relaxing part having a trench structure on the side of the drain region. Particularly, if current paths overlap in the field concentration region, impact ionization is likely to be generated. A high-energy electron generated by impact ionization moves along the side surface of the trench, and reaches a gate insulating film. In this structure, as a result that the gate insulating film is damaged, the reliability of the semiconductor device decreases. That is, the present inventors have found that it is necessary to examine the improvement in the semiconductor device including the field effect transistor having the field relaxing part having the trench structure.

Other objects and new features will be apparent from the descriptions of the present specification and the accompanying drawings.

A semiconductor device according to one embodiment includes a field effect transistor having a field relaxing part. This field relaxing part has a trench which is formed in a substrate, a charge capture film which is formed on a side wall of the trench, and an insulating film which is formed over the charge capture film and embedded in the trench.

According to one embodiment, it is possible to improve the reliability of the semiconductor device.

### BRIEF DESCRIPTION OF THE DRAWINGS

FIG. 1 is a diagram illustrating a device structure of an LDMOSFET in the related technique.

FIG. 2 is a cross sectional view showing a device structure of an LDMOSFET in an embodiment.

FIG. 3 is a diagram for explaining that damage to a gate insulating film is suppressed, according to a first feature point of the embodiment.

FIG. 4 is a diagram illustrating a structure in which a field relaxing part without a charge capture film is sandwiched between a p⁺-type semiconductor region and a p⁻-type semiconductor region, as a schematic first capacitance element.

FIG. 5 is a diagram illustrating a state in which a negative voltage is applied to the p⁺-type semiconductor region of the first capacitance element illustrated in FIG. 4.

FIG. 6 is a diagram illustrating a structure in which the field relaxing part with the charge capture film is sandwiched between the p⁺-type semiconductor region and the p⁻-type semiconductor region, as a schematic second capacitance element.

FIG. 7 is a diagram illustrating a state in which a negative voltage is applied to the p⁺-type semiconductor region of the second capacitance element illustrated in FIG. 6.

FIG. 8 is a schematic diagram illustrating a configuration example for forming a charge capture film on the side wall and also the bottom surface of the trench, in the field relaxing part having the trench structure.

FIG. 9 is a schematic diagram illustrating a configuration example in which a second feature point is embodied in the embodiment for forming the charge capture film only on the side wall of the trench, in the field relaxing part having the trench structure.

FIG. 10 is a cross sectional view showing a manufacturing process of a semiconductor device in FIG. 10.

FIG. 11 is a cross sectional view showing a manufacturing process of the semiconductor device, following that of FIG. 10.

FIG. 12 is a cross sectional view showing a manufacturing process of the semiconductor device, following that of FIG. 11.

FIG. 13 is a cross sectional view showing a manufacturing process of the semiconductor device, following that of FIG. 12.

FIG. 14 is a cross sectional view showing a manufacturing process of the semiconductor device, following that of FIG. 13.

FIG. 15 is a cross sectional view showing a manufacturing process of the semiconductor device, following that of FIG. 14.

FIG. 16 is a cross sectional view showing a manufacturing process of the semiconductor device, following that of FIG. 15.

FIG. 17 is a cross sectional view showing a manufacturing process of the semiconductor device, following that of FIG. 16.

FIG. 18 is a cross sectional view showing a manufacturing process of the semiconductor device, following that of FIG. 17.

FIG. 19 is a diagram for explaining that there are two methods for injecting charges into a charge capture film.

FIG. 20 is a diagram illustrating a schematic configuration of a film formation device for forming the charge capture film, using a CVD method.

FIG. 21 is a flowchart for explaining a mechanism for enabling injection of charges to the charge capture film, by turning on (on-operation) an LDMOSFET after manufactured.

FIG. 22 is a cross sectional view showing a schematic configuration of an LDMOSFET in a modification 1.

FIG. 23 is a cross sectional view showing a schematic configuration of an LDMOSFET in a modification 2.

### DETAILED DESCRIPTION

In the following preferred embodiments, if necessary for convenience sake, descriptions will be made to divided plural sections or preferred embodiments, however, unless otherwise specified, they are not mutually irrelevant, but one is in relations of modifications, details, supplementary explanations of a part or whole of the other.

In the following preferred embodiments, in the case of reference to the number of an element (including its quantity, numeric value, amount, range), unless otherwise specified and unless clearly limited in principle, the present invention is not limited to the specified number, and a number over or below the specified one may be used.

In the following preferred embodiments, needless to say, the constituent elements (including the element steps) are not necessarily indispensable, unless otherwise specified and unless considered that they are obviously required in principle.

Similarly, in the following preferred embodiments, in the reference of the forms of the constituent elements or the positional relationships, they intend to include those approximating or similar substantially to the forms and like, unless otherwise specified and unless considered that they are obviously not required in principle. This is also true of the foregoing numerical values and the range.

In the entire illustrations for explaining the preferred embodiments, the same members are generally identified by the same reference numeral, and thus will not be described repeatedly over and over. For the sake of easy illustration, hatching may be provided even in plan view.

### <Examine Improvement of Related Technique>

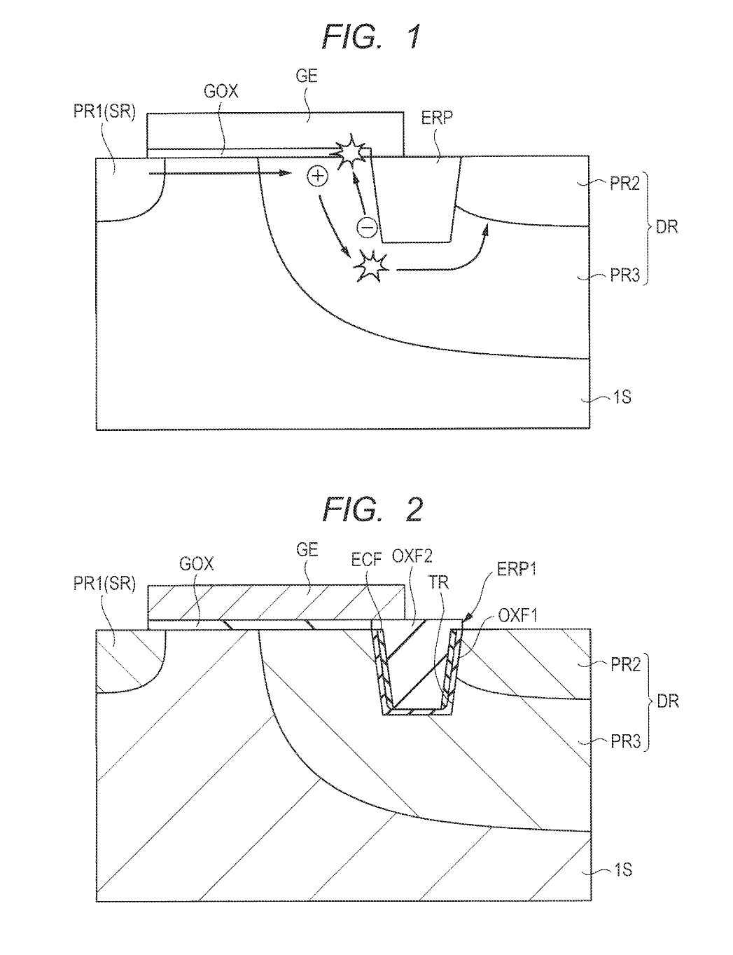

FIG. 1 is a diagram illustrating an example of a schematic device structure of an LDMOSFET (Laterally Diffused Metal Oxide Semiconductor Field Effect Transistor) of the related technique.

The “related technique” in this specification is a technique having a problem which has been newly found by the inventors, thus is not a known related art. However, it is a technique disclosed with the intention of the prior art (unknown technique) based on a new technical idea.

In FIG. 1, the LDMOSFET of the related technique has a source region SR and a drain region DR which are separately formed in a semiconductor substrate 1S. For example, the source region SR is formed from a p-type semiconductor region PR1, while the drain region DR is formed from a p-type semiconductor region PR2 and a p-type semiconductor region PR3. At this time, as illustrated in FIG. 1, the p-type semiconductor region PR2 is contained in the p-type semiconductor region PR3 having an impurity concentration lower than that of the p-type semiconductor region PR2. As illustrated in FIG. 1, a field relaxing part ERP is formed in the semiconductor substrate 1S, in a manner that it is in contact with the p-type semiconductor region PR2 and the p-type semiconductor device PR3 which are included in the drain region DR. Further, the LDMOSFET in the related technique has a gate insulating film GOX formed over the semiconductor substrate 1S between the source region SR and the field relaxing part ERP, and has a gate electrode GE over this gate insulating film GOX.

In this p-channel (p-type) LDMOSFET in the related technique, as illustrated in FIG. 1, if a gate voltage greater than a threshold voltage (absolute value) is applied to the gate electrode GE, a channel is formed on the surface of the semiconductor substrate 1S between the source region SR and the p-type semiconductor region PR3 for forming a part of the drain region DR. As a result, if a potential difference is provided between the source region SR (0V) and the drain region DR (negative voltage), as illustrated in FIG. 1, a hole current flows through a detour path, in the order of the source region SR→the channel→the p-type semiconductor region PR3→the lower part of the field relaxing part ERP→the p-type semiconductor region PR2.

Even if a negative voltage having a great absolute value is applied to the drain region DR, the path of the hole current in the drain region DR is a detour path, with the existence of the field relaxing part ERP. Thus, it is possible to realize a long distance (the distance of the detour path) between the p-type semiconductor region PR1 included in the source region SR and the p-type semiconductor region PR2 included in a part of the drain region DR. In the LDMOSFET in the related technique, it is possible to ensure the withstand voltage between the source region SR and the drain region DR with the existence of the field relaxing part ERP. That is, the field relaxing part ERP is to have a function for improving the withstand voltage between the source region SR in the LDMOSFET and the drain region DR.

However, according to the examination by the present inventors, it is found that a region having a high field intensity is generated in the p-type semiconductor region PR3 in the vicinity of the bottom corner part of the field relaxing part ERP, if a negative voltage having a great absolute value is applied to the drain region DR of the LDMOSFET. If the paths of hole currents overlap in the region having the high field intensity, impact ionization is generated, thereby forming pairs of holes and electrons. As illustrated in FIG. 1, according to the examination by the present inventors, high energy electrons (hot electrons) generated by the impact ionization move to the surface of the semiconductor substrate 1S, along the side wall of the field relaxing part ERP. As a result, the high energy electrons collide with the gate insulating film GOX formed on the surface of the semiconductor substrate 1S. Occurrence of this phenomenon continuously gives damage to the end part of the gate insulating film GOX. Then, the reliability of the gate insulating film GOX is decreased. As a result, in the LDMOSFET in the related technique, there is room for improvement from the perspective of improving the reliability of the LDMOSFET. In this embodiment, some device is provided for improving the reliability of the LDMOSFET. Descriptions will now be made to a technical idea in the embodiment having this given device, with reference to the accompanying drawings.

### <Basic Idea in Embodiment>

The basic idea of this embodiment is based on knowledge that a region having the high field intensity is generated in the vicinity of the bottom corner of the field relaxing part, and that the electrons having the high energy give damage to the gate insulating film. Note that the high energy electrons are generated due to the impact ionization resulting from that the current paths overlap in the region having the high field intensity. Particularly, the basic idea of this embodiment is based on an idea that it is possible to suppress a decrease in the reliability of the gate insulating film GOX based on a particular mechanism, if occurrence of a region having the high field intensity can be suppressed. Note that this mechanism is that the fundamental factor causing a decrease in the reliability of the gate insulating film results from occurrence of a region having the high field intensity in the vicinity of the bottom corner part of the field relaxing part. Descriptions will hereinafter be made to a device structure of the LDMOSFET in this embodiment to embody this basic idea.

### <Device Structure of LDMOSFET>

FIG. 2 is a cross sectional view showing a device structure of the LDMOSFET of this embodiment. In FIG. 2, the LDMOSFET of this embodiment has the source region SR and the drain region DR which are separately formed in the semiconductor substrate 1S. For example, the source region SR is formed from the p-type semiconductor region PR1, while the drain region DR is formed from the p-type semiconductor region PR2 and the p-type semiconductor region PR3. At this time, as illustrated in FIG. 2, the p-type semiconductor region PR2 is contained in the p-type semiconductor region PR3 having an impurity concentration lower than that of the p-type semiconductor region PR2.

As illustrated in FIG. 2, a field relaxing part ERP1 is formed in the semiconductor substrate 1S, in contact both with the p-type semiconductor region PR2 and the p-type semiconductor region PR3 included in the drain region DR. In this manner, the drain region DR has the p-type semiconductor region PR2 having a first impurity concentration and the p-type semiconductor region PR3, having a second impurity concentration lower than the first impurity concentration and containing the p-type semiconductor region PR2. The field relaxing part ERP1 is contained in the p-type semiconductor region PR3, inside the p-type semiconductor region PR2. That is, the LDMOSFET of this embodiment has the field relaxing part ERP1 contained in the drain region DR and formed in the semiconductor substrate 1S.

As illustrated in FIG. 2, this field relaxing part ERP1 has a trench structure. Particularly, the field relaxing part ERP1 has a trench TR, an insulating film OXF1, a charge capture film ECF, and an insulating film OXF2. The trench TR is formed in the semiconductor substrate 1S. The insulating film OXF1 is formed on the inner wall of the trench TR. The charge capture film ECF is formed over the insulating film OXF1 and formed only on the side wall of the trench TR. The insulating film OXF2 is formed over the charge capture film ECF and provided for filling the trench TR. In the LDMOSFET of this embodiment, the insulating film OXF1 intervenes between the side wall of the trench TR and the charge capture film ECF. The insulating film OXF1 is formed from, for example, a silicon oxide film. The charge capture film ECF is formed from a film having a function for accumulating charges, and is configured from a polysilicon film having conductivity or an insulating film having a trap level (defect level) for capturing the charges. Particularly, the insulating film having the trap level may, for example, be a silicon nitride film.

Further, as illustrated in FIG. 2, the LDMOSFET of this embodiment has a gate insulating film GOX formed over the semiconductor substrate 1S between the source region SR and the field relaxing part ERP1, and has a gate electrode GE over this gate insulating film GOX. For example, the gate insulating film GOX can be formed from a silicon oxide film. However, it is not limited to this film, and it may be formed from a high dielectric constant film (a hafnium oxide film) having a dielectric constant greater than that of the silicon oxide film. The gate electrode GE is formed, for example, from a polysilicon film. However, it is not limited to this, and may be formed from a metal film. The LDMOSFET of this embodiment is formed in this manner.

### <Features of Embodiment>

Descriptions will now be made to feature points of this embodiment. The first feature point of this embodiment is that the charge capture film ECF is provided on the side wall of the field relaxing part ERP1 having the trench structure, and that charges (electrons) are accumulated in this charge capture film ECF. According to the LDMOSFET of this embodiment, it is possible to suppress a decrease in the reliability of the gate insulating film GOX, and thus it is possible to improve the reliability of the semiconductor device.

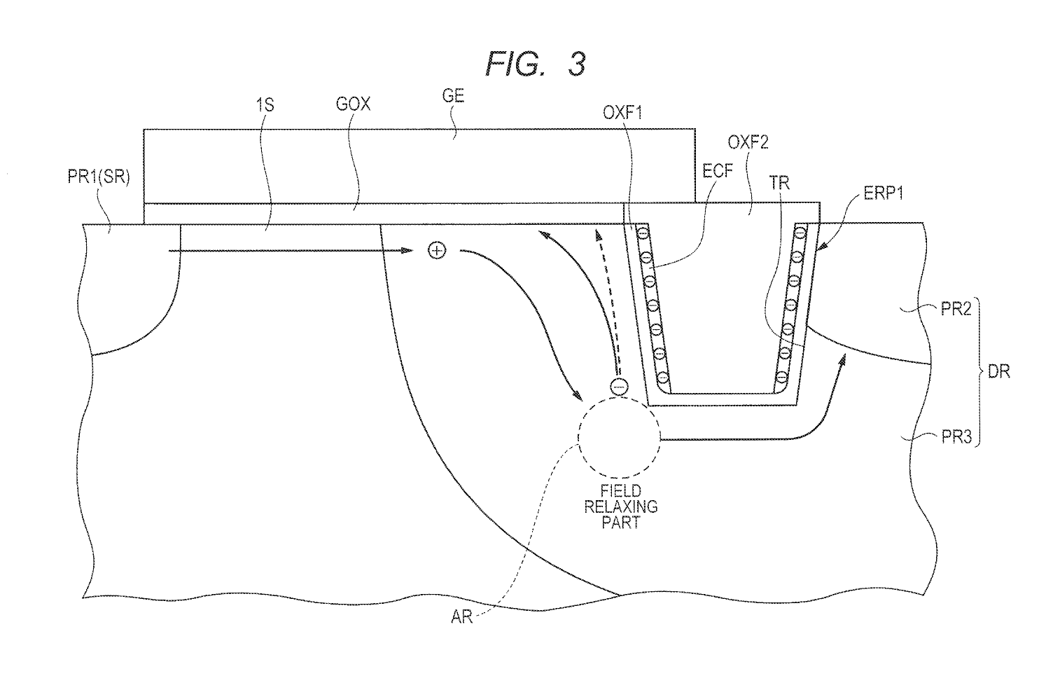

With reference to FIG. 3, descriptions will hereinafter be made that it is possible to suppress the decrease in the reliability of the gate insulating film GOX, according to the first feature point that the charge capture film ECF is provided on the side wall of the field relaxing part ERP1 having the trench structure and that charges (electrons) are accumulated in the charge capture film ECF.

FIG. 3 is a diagram for explaining that it is possible to suppress damage to the gate insulating film GOX, according to the first feature point of this embodiment. In FIG. 3, the charge capture film ECF is provided on the side wall of the trench TR of the field relaxing part ERP1 through the insulating film OXF1. Electrons are charged in this charge capture film ECF. It is possible to suppress occurrence of a region having high field intensity in the vicinity of the bottom corner of the field relaxing part ERP1, by the effect of the electrons accumulated in the charge capture film ECF. That is, the field intensity is relaxed in an area AR in the vicinity of the bottom corner of the field relaxing part ERP1 illustrated in FIG. 3. As a result, even if this area AR overlaps a current path, impact ionization is not likely to be generated. This implies that occurrence of pairs of the holes/electrons due to impact ionization is suppressed, in the area AR in the vicinity of the bottom corner of the field relaxing part ERP1. Thus, according to the first feature point of this embodiment, it is possible to improve the reliability of the gate insulating film GOX, as a result that the occurrence of electrons having high energy can be suppressed. Note that this occurrence gives damage to the gate insulating film GOX.

In this embodiment, because the electrons are accumulated in the charge capture film ECF, even if the electrons (hot electrons) having high energy are generated, it is suppressed that the hot electrons move along the side wall of the trench TR. This is because, for example, as illustrated in FIG. 3, the movement path of the hot electrons changes from the path of a dashed arrow to the path of a solid arrow, by electrical repulsive force between the hot electrons and the electrons accumulated in the charge capture film ECF. This enables to avoid collision of the hot electrons intensively at the end part of the gate insulating film GOX. This results in a decrease in the damage to the gate insulating film GOX, according to the first feature point of this embodiment. That is, according to the first feature point of this embodiment, the damage to the gate insulating film GOX is effectively suppressed, by a synergistic effect of an effect of relaxing the field intensity in the vicinity of the bottom corner of the field relaxing part ERP1 and an effect of dispersing the movement path of the hot electrons from the path along the side surface of the trench TR. According to the first feature point of this embodiment, it is possible to improve the reliability of the LDMOSFET, by the decrease in the damage to the gate insulating film GOX.

Descriptions will now be made to a mechanism for lowering the field intensity in the vicinity of the bottom corner of the field relaxing part ERP1, by accumulating the electrons in the charge capture film ECF.

In FIG. 3, the field relaxing part ERP1 having the trench structure is sandwiched between the p-type semiconductor region PR2 and the p-type semiconductor region PR3. In the structure that the field relaxing part ERP1 is sandwiched between the p-type semiconductor region PR2 and the p-type semiconductor region PR3, schematically, the p-type semiconductor region PR2 can be assumed as one electrode, the p-type semiconductor region PR3 can be assumed as the other electrode, and the field relaxing par ERP1 including an insulator (a dielectric) and inserted between the one electrode and the other electrode can be assumed as a capacitive element. Qualitative descriptions will now clearly be made to a mechanism for lowering the field intensity in the vicinity of the bottom corner of the field relaxing part ERP1 by accumulating the electrons in the charge capture film ECF, using this schematic capacitive element.

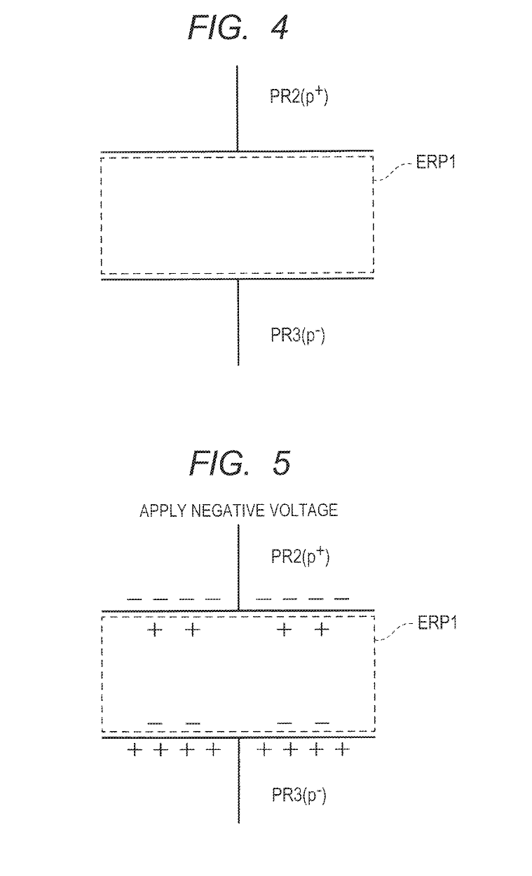

FIG. 4 is a diagram illustrating, as a schematic first capacitive element, a structure in which the field relaxing part ERP1 without the charge capture film ECF is sandwiched between the p-type semiconductor region RP2 (p⁺-type semiconductor region) and the p-type semiconductor region PR3 (p⁻-type semiconductor region). FIG. 5 is a diagram illustrating a state in which a negative voltage is applied to the p-type semiconductor region PR2 (p⁺-type semiconductor region) of the first capacitive element illustrated in FIG. 4. As illustrated in FIG. 5, if a negative voltage is applied to the p-type semiconductor region PR2 (p⁺-type semiconductor region) of the first capacitive element, minus charges are accumulated in a first electrode (one electrode) of the first capacitive element including the p-type semiconductor region PR2 (p⁺-type semiconductor region). Plus charges are accumulated in a second electrode (the other electrode) of the first capacitive element including the p-type semiconductor region PR3 (p⁻-type semiconductor region). At this time, a polarization phenomenon occurs in the field relaxing part ERP1 (insulator, dielectric) sandwiched between the first electrode and the second electrode. Specifically, as illustrated in FIG. 5, the plus charges are induced on the side of the first electrode of the field relaxing part ERP1 (insulator, dielectric), while minus charges are induced on the side of the second electrode of the field relaxing part ERP1 (insulator, dielectric). As a result, for example, in the inner part of the p-type semiconductor region PR3 (p⁻-type semiconductor region), an electric field is generated based on the charges corresponding to a difference mainly between the plus charges accumulated in the second electrode and the minus charges induced on the side of the second electrode of the field relaxing part ERP1 (insulator, dielectric). For example, in FIG. 5, eight plus charges are accumulated in the second electrode, while four minus charges are induced on the side of the second electrode of the field relaxing part ERP1 (insulator, dielectric). Thus, the number of minus charges corresponding to the difference is four, and the field intensity generated internally in the p-type semiconductor region PR3 (p⁻-type semiconductor region) can be determined, based on the four plus charges.

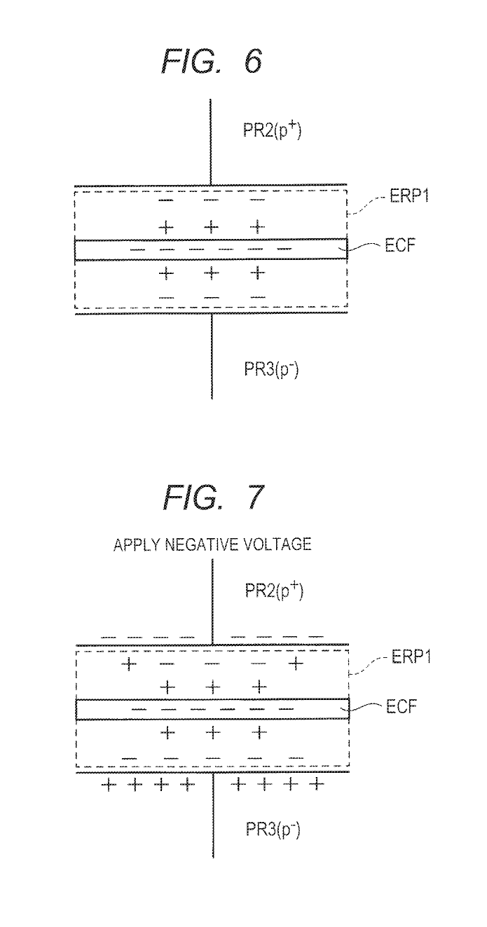

Subsequently, FIG. 6 is a diagram illustrating, as a schematic second capacitive element, a structure in which the field relaxing part ERP1 having the charge capture film ECF is sandwiched between the p-type semiconductor region RP2 (p⁺-type semiconductor region) and the p-type semiconductor region PR3 (p⁻-type semiconductor region). In FIG. 6, because minus charges are accumulated in the charge capture film ECF, a polarization phenomenon occurs in the field relaxing part ERP1 (insulator, dielectric). Particularly, as illustrated in FIG. 6, minus charges are induced on the side of the first electrode of the field relaxing part ERP1 (insulator, dielectric), and minus charges are induced also on the side of the second electrode of the field relaxing part ERP1 (insulator, dielectric). For example, in FIG. 6, three minus charges are induced on the side of the first electrode of the field relaxing part ERP1 (insulator, dielectric), and also three minus charges are induced on the side of the second electrode of the field relaxing part ERP1 (insulator, dielectric). That is, as the schematic second capacitive element, in a structure in which the field relaxing part ERP1 having the charge capture film ECF is sandwiched between the p-type semiconductor region PR2 (p⁺-type semiconductor region) and the p-type semiconductor region PR3 (p⁻-type semiconductor region), even if no potential difference is made between both electrodes of the second capacitive element, a polarization phenomenon occurs in the field relaxing part ERP1 (insulator, dielectric), due to the minus charges accumulated in the charge capture film ECF.

FIG. 7 is a diagram illustrating a state in which a negative voltage is applied to the p-type semiconductor region PR2 (p⁺-type semiconductor region) of the second capacitive element illustrated in FIG. 6. As illustrated in FIG. 7, if a negative voltage is applied to the p-type semiconductor region PR2 (p⁺-type semiconductor region), minus charges are accumulated in the first electrode (one electrode) of the first capacitive element including the p-type semiconductor region PR2 (p⁺-type semiconductor region). On the other hand, plus charges are accumulated in the second electrode (the other electrode) of the first capacitive element including the p-type semiconductor region PR3 (p⁻-type semiconductor region). At this time, further, a polarization phenomenon occurs in the field relaxing part ERP1 (insulator, dielectric) sandwiched between the first electrode and the second electrode. Particularly, as illustrated in FIG. 7, plus charges are induced on the side of the first electrode of the field relaxing part ERP1 (insulator, dielectric), while minus charges are induced on the side of the second electrode of the field relaxing part ERP1 (insulator, dielectric). As a result, in the inner part of the p-type semiconductor region PR3 (p⁺-type semiconductor region), an electric field is generated based on the charges corresponding to a difference mainly between the plus charges accumulated in the second electrode and the minus charges induced on the side of the second electrode of the field relaxing part ERP1 (insulator, dielectric). Particularly, in FIG. 7, eight plus charges are accumulated in the second electrode, while five minus charges are induced on the side of the second electrode of the field relaxing part ERP1 (insulator, dielectric). Thus, the number of plus charges corresponding to this difference is three, and the field intensity generated internally in the p-type semiconductor region PR3 (p⁻-type semiconductor region) can be determined, based on the three plus charges.

That is, in the second capacitance element illustrated in FIG. 7, on the side of the second electrode of the field relaxing part ERP1 (insulator, dielectric), polarized charges in combination of polarized charges (three minus charges illustrated in FIG. 6) caused by the minus charges accumulated in the charge capture film ECF and polarized charges caused by occurrence of the potential difference between both electrodes of the second capacitance element. That is, in FIG. 7, eight plus charges are accumulated in the second electrode, while five minus charges are induced on the side of the second electrode of the field relaxing part ERP1 (insulator, dielectric). Thus, the number of plus charges corresponding to this difference is three. The field intensity generated in the inner part of the p-type semiconductor region PR3 (p⁻-type semiconductor region) is determined, based on these three plus charges.

In comparison of FIG. 5 and FIG. 7, in the first capacitive element of FIG. 5 schematically illustrating the structure in which the field relaxing part ERP1 without the charge capture film ECF is sandwiched between the p-type semiconductor region PR2 (p⁺-type semiconductor region) and the p-type semiconductor region PR3 (p⁻-type semiconductor region), the field intensity generated in the inner part of the p-type semiconductor region PR3 (p⁻-type semiconductor region) is determined, based on the four plus charges. In the second capacitive element of FIG. 7 schematically illustrating the structure in which the field relaxing part ERP1 having the charge capture film ECF is sandwiched between the p-type semiconductor region PR2 (p⁺-type semiconductor region) and the p-type semiconductor region PR3 (p⁻-type semiconductor region), the field intensity generated in the inner part of the p-type semiconductor region PR3 (p⁻-type semiconductor region) is determined based on the three plus charges.

For example, according to Gauss Law, the field intensity, on a closed surface, which is generated based on four plus charges existing in the closed surface is greater than the field intensity, on a closed surface, which is generated based on three plus charges existing in the closed surface. In other words, the field intensity, on the closed surface, which is generated based on the three plus charges existing in the closed surface is lower than the field intensity, on the closed surface, which is generated based on the four plus charges existing in the closed surface. This implies that the field intensity generated in the p-type semiconductor region PR3 (p⁻-type semiconductor region) can be lower in the second capacitive element (see FIG. 7) having the charge capture film ECF, than the first capacitive element (see FIG. 5) without the charge capture film ECF. In other words, it is possible to suppress occurrence of the region with the high field intensity in the vicinity of the bottom corner of the field relaxing part ERP1, according to the first feature point of this embodiment that the charge capture film ECF is provided on the side wall of the field relaxing part ERP1 having the trench structure and that charges (electrons) are accumulated in the charge capture film ECF. As a result, according to the first feature point of this embodiment, even if the area AR illustrated in FIG. 3 overlaps the current path of the hole current, impact ionization is not likely to be generated. According to the first feature point of this embodiment, in the area AR in the vicinity of the bottom corner of the field relaxing part ERP1, it is possible to suppress occurrence of pairs of holes/electrons caused by the impact ionization, thus suppressing occurrence of hot electrons which cause damage to the gate insulating film GOX. This results in improving the reliability of the gate insulating film GOX. Based on the above mechanism, according to this embodiment, it is possible to improve the reliability of the gate insulating film GOX of the LDMOSFET, resulting in improving the reliability of the semiconductor device including the LDMOSFET of this embodiment.

For example, as illustrated in FIG. 3, a second feature point of this embodiment is that the charge capture film ECF is formed only on the side wall of the trench TR, in the field relaxing part ERP1 having the trench structure. In other words, according to the second feature point of this embodiment, the charge capture film ECF is not formed on the bottom surface of the trench TR. Thus, it is possible to improve the performance of the LDMOSFET of this embodiment. Particularly, according to the second feature point of this embodiment, it is possible to lower the on-resistance of the LDMOSFET, thus enabling to improve the performance of the LDMOSFET.

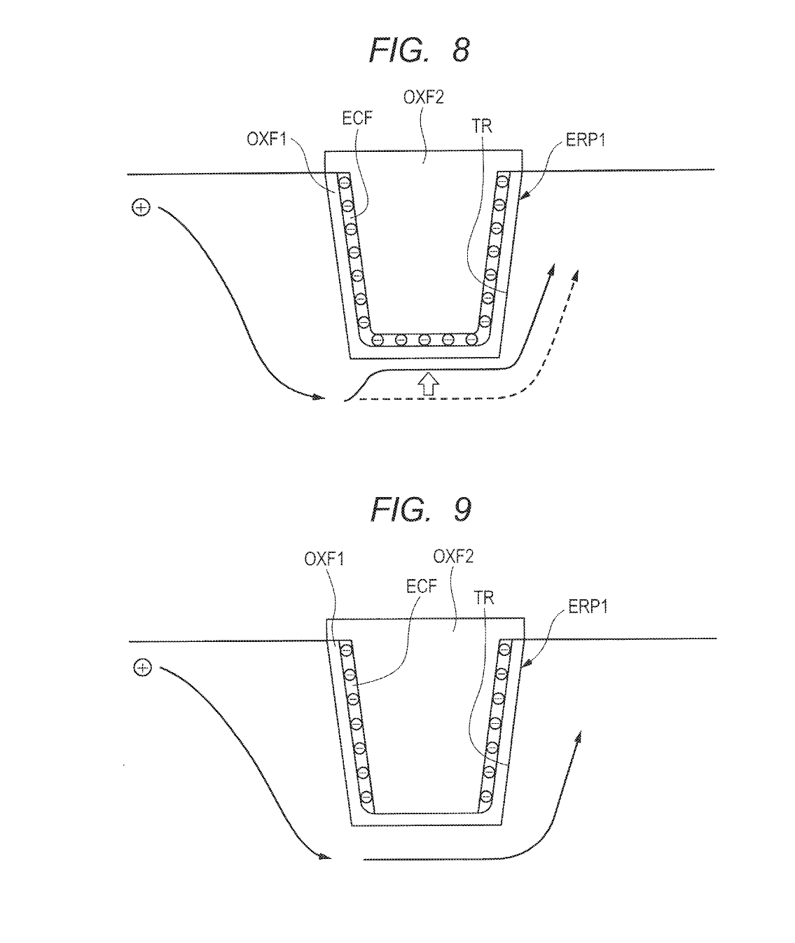

Descriptions will hereinafter be made to this point. FIG. 8 is a schematic diagram illustrating a configuration example for forming the charge capture film ECF on the side wall and also the bottom surface of the trench TR, in the field relaxing part ERP1 having the trench structure. In the configuration example illustrated in FIG. 8, the charge capture film ECF in which minus charges are accumulated also in the bottom surface of the trench TR is formed. Thus, as illustrated in FIG. 8, at the time when the LDMOSFET is turned on, if a hole current flows underneath the bottom surface of the trench TR, electric attractive force acts in a manner that the holes included in the hole current approach the bottom surface of the trench TR, by the minus charges accumulated in the charge capture film ECF formed on the bottom surface of the trench TR. As a result, as illustrated in FIG. 8, the current path of the hole current is moved to the position from the dashed arrow to the solid arrow. This implies that the current path of the hole current approaches the bottom surface of the trench TR. This implies that the holes included in the hole current are easily influenced by roughness (surface roughness) of the bottom surface of the trench TR. That is, it implies that if the current path of the hole current approaches the bottom surface of the trench TR, the holes included in the hole current are likely to be scattered by irregularities of the surface of the bottom surface of the trench TR. This implies that the on-resistance of the LDMOSFET increases. That is, as illustrated in FIG. 8, if the charge capture film ECF is formed also on the bottom surface of the trench TR, the current path of the hole current approaches the bottom surface of the trench TR. As a result of this, the hole current is easily influenced by the scattering due to the irregularities of the bottom surface of the trench TR. Then, some side effect, for example, an increase in the on-resistance of the LDMOSFET may occur.

FIG. 9 is a schematic diagram illustrating a configuration example in which a second feature point is embodied in this embodiment for forming the charge capture film only on the side wall of the trench TR, in the field relaxing part ERP1 having the trench structure. As illustrated in FIG. 9, when the charge capture film ECF is not formed on the bottom surface of the trench TR, the current path of the hole current is not easily influenced by the irregularities of the bottom surface of the trench TR, without being attracted to the bottom surface of the trench TR. That is, in the configuration example of FIG. 9 illustrating the second feature point of this embodiment, the holes included in the hole current are not likely to be scattered due to the irregularities of the bottom surface of the trench TR. As a result, according to the second feature point of this embodiment, it is possible to suppress an increase in the on-resistance of the LDMOSFET. Thus, according to the second feature point of this embodiment, it is possible to improve the performance of the semiconductor device including the LDMOSFET, because of the suppression of the increase in the on-resistance of the LDMOSFET.

Accordingly, in combination of the first feature point and the second feature point of this embodiment, it is possible to improve the reliability of the gate insulating film GOX of the LDMOSFET, without occurrence of the side effect, such as the increase in the on-resistance of the LDMOSFET. Thus, according to the semiconductor device including the LDMOSFET in which the first feature point and the second feature point of this embodiment are embodied, it is possible to realize a remarkable effect of improving the reliability of the semiconductor device, without lowering the performance of the semiconductor device.

It is preferred that the LDMOSFET of this embodiment include the above-described first feature point and the second feature point. However, it is not limited to this example, and it may include only the first feature point. That is, the charge capture film ECF may be formed not only on the side wall of the trench TR, but also on the bottom surface thereof. This is because it is possible to attain an effect of relaxing the field intensity in the vicinity of the bottom corner of the trench TR, even when the charge capture film ECF is formed on the bottom surface.

### <Manufacturing Method of LDMOSFET>

The LDMOSFET of this embodiment is configured as described above. Descriptions will hereinafter be made to its manufacturing method, with reference to the drawings.

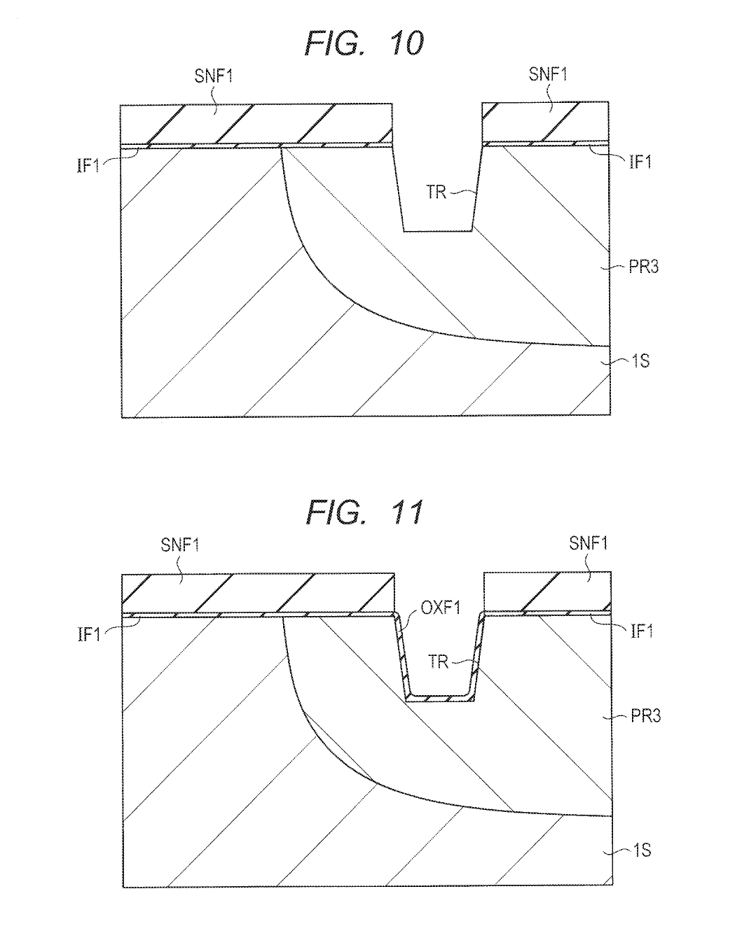

As described in FIG. 10, a semiconductor substrate (a silicon substrate) 1S is prepared. For example, using a photolithography technique and an ion injection technique, the p-type semiconductor region PR3 is formed in the semiconductor substrate 1S. After this, an insulating film IF1 is formed over the surface of the semiconductor substrate 1S, and a silicon nitride film SNF1 is formed over this insulating film IF1. The insulating film IF1 is formed from, for example, a silicon oxide film (a liner film), and can be formed using, for example, a thermal oxidation method. The silicon nitride film SNF1 can be formed using, for example, a CVD (Chemical Vapor Deposition) method. After this, using a photolithography technique and an etching technique, the silicon nitride film SNF1 is patterned. The patterning of the silicon nitride film SNF1 is performed to open a region in which the trench TR is formed. Then, the insulating film IF1 and the semiconductor substrate 1S are etched, using the patterned silicon nitride film SNF1 as a hard mask. As a result, the trench TR can be formed in the semiconductor substrate 1S. The trench TR is contained in the p-type semiconductor region PR3.

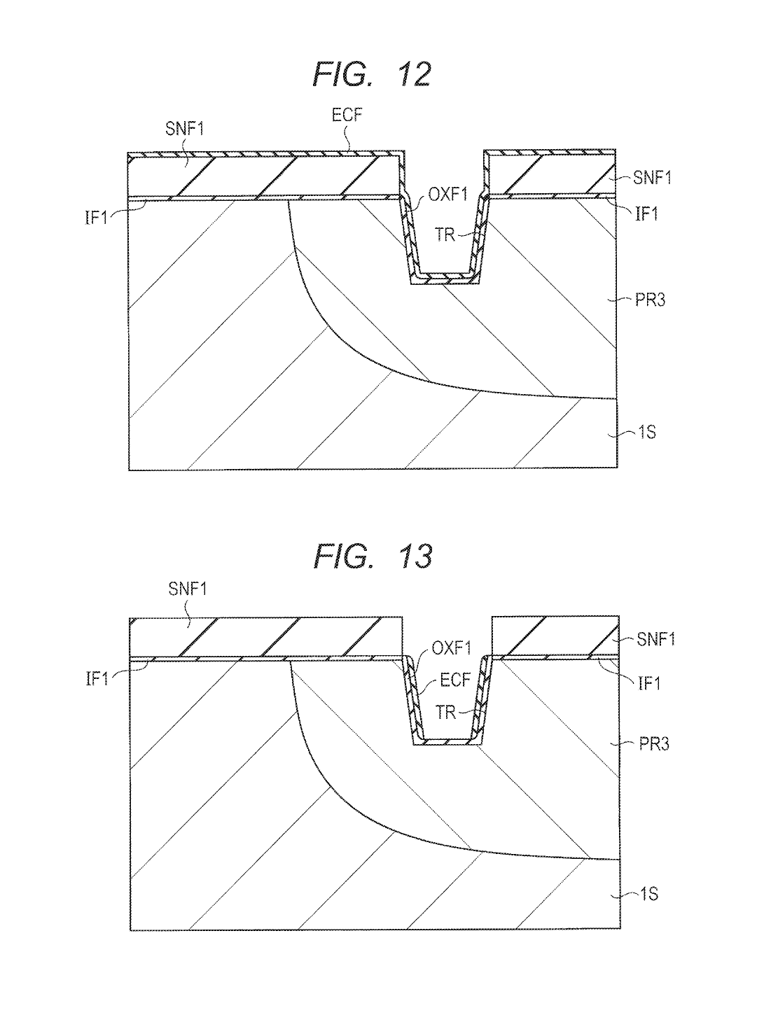

Subsequently, as illustrated in FIG. 11, the insulating film OXF1 is formed on the inner wall of the trench TR. This insulating film OXF1 is formed, for example, from a silicon oxide film, and formed using, for example, a thermal oxidation method. After this, as illustrated in FIG. 12, the charge capture film ECF is formed over the silicon nitride film SNF1 including the insulating film OXF1 formed on the inner wall of the trench TR. This charge capture film ECF is formed from, for example, a polysilicon film or an insulating film (a silicon nitride film) having a trap level, and can be formed using, for example, a plasma CVD method.

As illustrated in FIG. 13, anisotropic etching, representatively, plasma etching, is performed for the charge capture film ECF, thereby removing the charge capture film ECF formed over the bottom surface of the trench TR and removing the charge capture film ECF formed over the silicon nitride film SNF1, via the insulating film OXFF1. As a result, as illustrated in FIG. 13, it is possible to form the charge capture film ECF only on the side wall of the trench TR, via the insulating film OXF1.

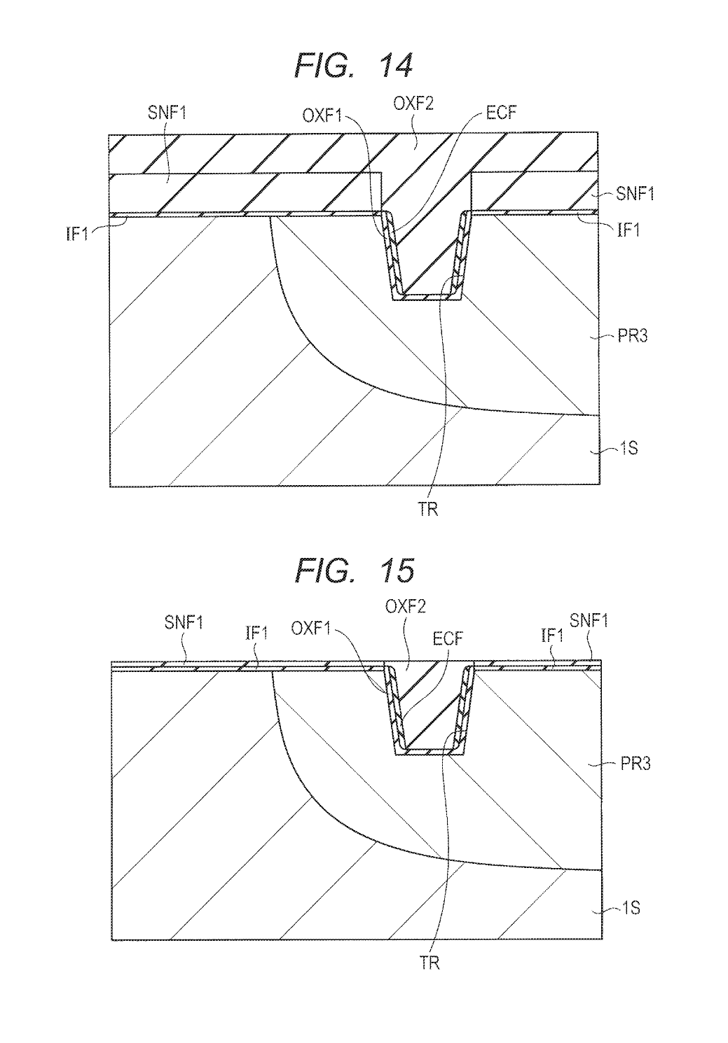

As illustrated in FIG. 14, the insulating film OXF2 is formed over the silicon nitride film SNF1 including the inside of the trench TR. In this process, the insulating film OXF2 is embedded inside the trench TR. The insulating film OXF2 is formed, for example, from a silicon oxide film, and is formed using, for example, a CVD method.

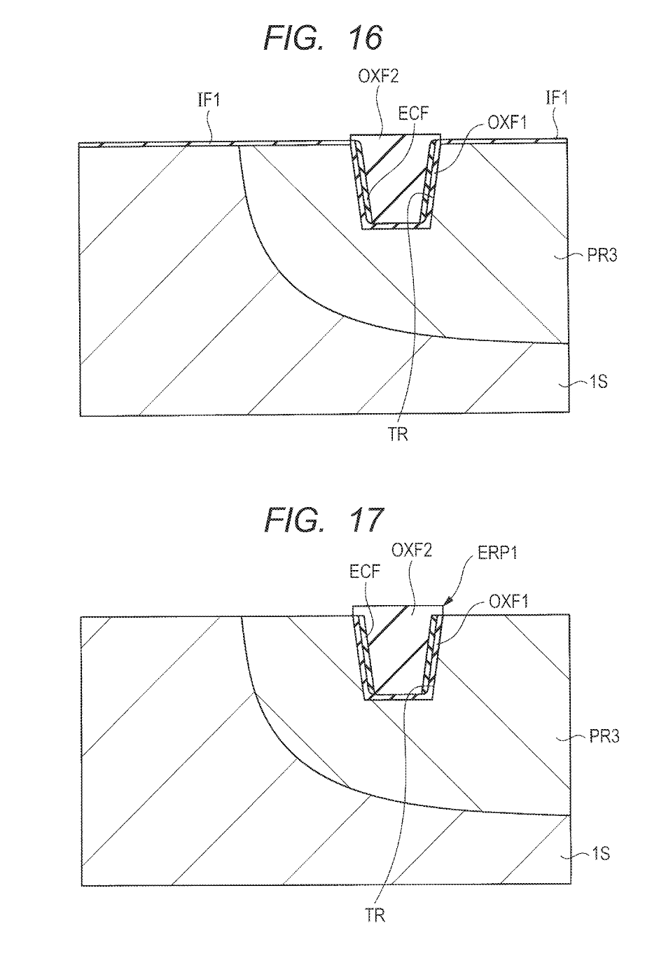

After this, as illustrated in FIG. 15, the insulating film OXF2 is removed, and a part of the silicon nitride film SNF1 is also removed, using a CMP (Chemical Mechanical Polishing) method, for example. As illustrated in FIG. 16, the remaining silicon nitride film SNF1 is removed. For removing the silicon nitride film SNF1, wet etching, representatively, using a heat phosphoric acid can be performed.

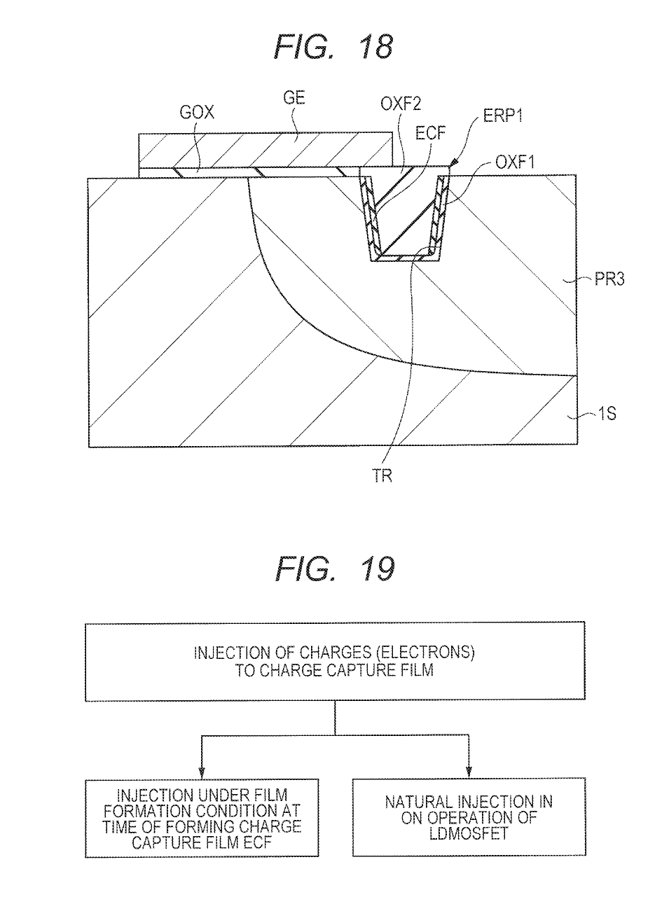

As illustrated in FIG. 17, the insulating film IF1 which is exposed by removing the silicon nitride film SNF1 is removed. The removing of the insulating film IF1 is performed using, for example, wet etching. Then, it is possible to form the field relaxing part having the trench structure on the semiconductor substrate 1S. After this, as illustrated in FIG. 18, the gate insulating film GOX is formed over the semiconductor substrate 1S. The gate insulating film GOX is formed, for example, from the silicon oxide film, and is formed using, for example, a thermal oxidation method. After the polysilicon film is formed over the gate insulating film GOX, the polysilicon film is patterned using a photolithography technique and an etching technique, thereby forming a gate electrode GE.

After this, as illustrated in FIG. 2, the p-type semiconductor region PR1 and the p-type semiconductor region PR2 are formed in the semiconductor substrate 1S, using the photolithography technique and the ion injection method. Then, it is possible to form the source region SR including the p-type semiconductor region PR1, the p-type semiconductor region PR2, and the drain region DR including p-type semiconductor region PR3 whose impurity concentration is lower than that of the p-type semiconductor region PR2. In this manner, it is possible to manufacture the LDMOSFET according to this embodiment.

### <Injection Method of Charges (Electrons) to Charge Capture Film>

For example, as illustrated in FIG. 3, the feature point of this embodiment is that the charge capture film ECF is provided on the side wall of the field relaxing part ERP1 having the trench structure, and that charges (minus ions, electrons) are accumulated in this charge capture film ECF. As a result, it is possible to relax the field intensity in the vicinity of the bottom surface of the trench TR, by the effect of the charges accumulated in the charge capture film ECF. That is, to relax the field intensity in the vicinity of the bottom surface of the trench TR, the charges are necessarily injected into the charge capture film ECF.

For example, there are a plurality of methods for injecting the charges into the charge capture film ECF. Descriptions will hereinafter be made to the plurality of methods for injecting the charges into the charge capture film ECF. FIG. 19 is a diagram for explaining that there are two methods for injecting charges into the charge capture film ECF. As illustrated in FIG. 19, the first method for injecting charges into the charge capture film ECF is a method for injecting charges into the charge capture film ECF based on a film formation condition at the time of forming the charge capture film ECF. According to this first method, the charges are injected into the charge capture film ECF in the stage of manufacturing the LDMOSFET.

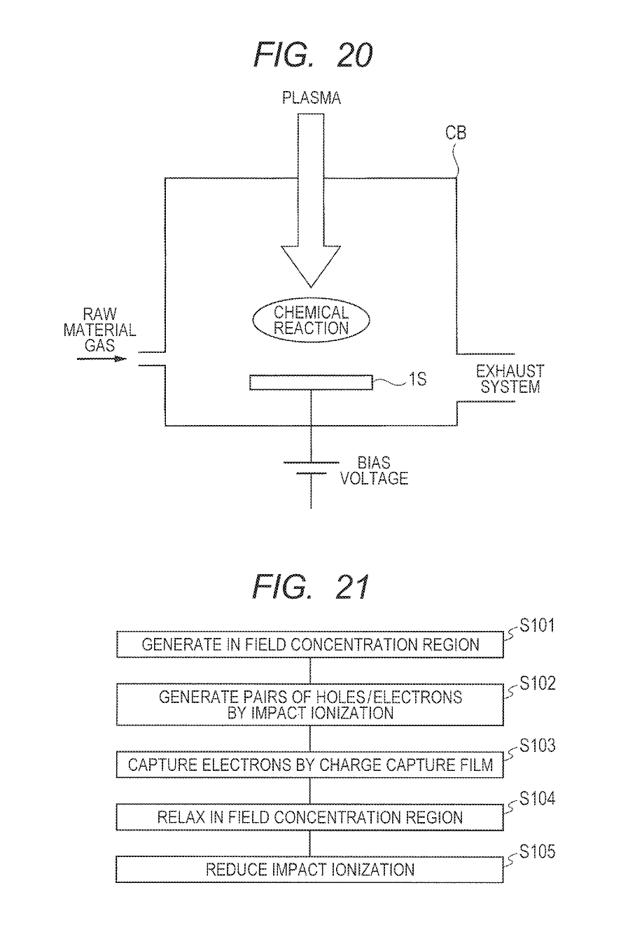

Particularly, in the first method, for example, as illustrated in FIG. 12, the film formation condition is adjusted in the process of forming the charge capture film ECF using the CVD method. FIG. 20 is a diagram illustrating a schematic configuration of a film formation device which forms the charge capture film ECF, using the CVD method. In FIG. 20, a semiconductor substrate IS (a semiconductor wafer) is arranged in a chamber CB. In the CVD method, raw material gas is introduced into the chamber CB, and the raw material gas is chemically reacted using plasma, thereby forming the charge capture film ECF. The remaining gas is exhausted from an exhaust system. At this time, in this embodiment, as illustrated in FIG. 20, a bias voltage is applied to the semiconductor substrate 1S. Particularly, a bias voltage is applied to the semiconductor substrate 1S in a manner that the potential on the side of the semiconductor substrate 1S becomes positive. That is, in this embodiment, according to the feature of the film formation condition in the process of forming the charge capture film ECF using the CVD method, a substrate bias is applied for causing the potential of the semiconductor substrate 1S to be positive. The minus ions existing in the plasma are attracted to the semiconductor substrate 1S to which a positive potential is applied, by Coulomb attraction. As a result of this, the minus ions existing in the plasma are taken into the charge capture film ECF.

Further, as an option of the first method, a continuous additional process is performed, after the charge capture film ECF is formed, using a CVD method in a state in which a substrate bias is applied for causing the potential of the semiconductor substrate 1S to be positive. Subsequently, while maintaining a state of applying the substrate bias, ashing gas introduced instead of the raw material gas in the same chamber, thereby enabling to perform a plasma ashing process for the charge capture film ECF. In this case, the electrons are taken into the charge capture film ECF.

After this, for example, as illustrated in FIG. 13, also when performing anisotropic etching for the charge capture film ECF, it is possible to inject charges into the charge capture film ECF by using a plasma etching method based on the condition of applying the substrate bias. According to the first method, the charges can be accumulated in the charge capture film ECF, using the manufacturing method of the LDMOSFET.

As the charge capture film ECF, it is possible to use the polysilicon film or an insulating film (for example, a silicon nitride film) having a trap level. However, the above-described first method can be applied both to a case in which the charge capture film ECF is formed from the polysilicon film and a case in which the charge capture film ECF is formed from the silicon nitride film. Note, however, that when the charge capture film ECF is formed from a polysilicon film, the charges accumulated in the polysilicon film exist in a conduction band. Thus, for example, when there is formed a leakage path of charges leaked from the charge capture film ECF, the charges accumulated in the polysilicon film are all leaked from this leakage path. When the charge capture film ECF is formed from the silicon nitride film, the charges accumulated in the silicon nitride film exist on discrete trap levels. Thus, for example, even when there is formed the leakage path of charges leaked from the charge capture film ECF, the charges accumulated in the silicon nitride film are not entirely leaked from this leakage path. Therefore, from the perspective of maintaining the charge keeping characteristic in the charge capture film ECF, it is preferred that the charge capture film ECF be formed from a silicon nitride film, rather than being formed from a polysilicon film.

As illustrated in FIG. 19, the second method for injecting charges into the charge capture film ECF is natural injection by turning on the LDMOSFET. According to this second method, it is possible to inject charges into the charge capture film ECF by turning on the LDMOSFET after manufactured, though charges are not injected into the charge capture film ECF in the stage of manufacturing the LDMOSFET. Descriptions will hereinafter be made to a mechanism for injecting charges into this charge capture film ECF.

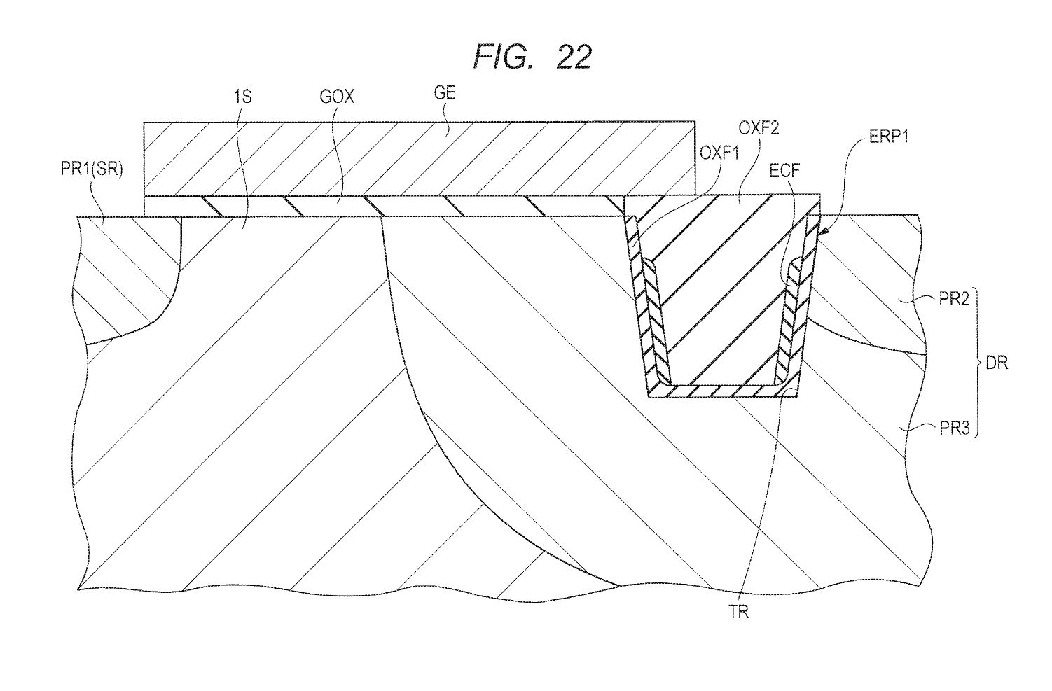

FIG. 21 is a flowchart for explaining the mechanism for injecting the charges into the charge capture film ECF, by turning on the LDMOSFET after manufactured.

For example, when the charge capture film ECF is formed from a silicon nitride film, the charges may not be accumulated in the charge capture film ECF, because its dielectric constant is higher than that of the silicon oxide film. In this case, the intensity of the field concentration region generated in the vicinity of the bottom corner of the trench TR is high (S101). In this state, if the LDMOSFET is turned on, a hole current flows through this field concentration region. As a result, holes are accelerated by the high intensity field, and the accelerated holes collide with the crystal lattice. Then, impact ionization occurs, resulting in generating pairs of holes and electrons (S102). After this, because the hot electrons generated due to the impact ionization have high energy, they overcome the potential barrier of the silicon oxide film (the insulating film (OXF1) formed in the trench TR, and are taken into the trap levels of the silicon nitride film as the charge capture film ECF (S103). By this, the charges can be accumulated in the charge capture film ECF. If the charges are accumulated in the charge capture film ECF, the field intensity of the field concentration region is relaxed (S104). As a result, occurrence of the impact ionization is reduced (S105), thus suppressing generation of the hot electrons. This suppresses degradation of the gate insulating film GOX due to the hot electrons. According to the second method, it is possible to accumulate the charges in the charge capture film ECF, by turning on the LDMOSFET.

A polysilicon film or an insulating film (for example, a silicon nitride film) having a trap level may be used as the charge capture film ECF. However, the above-described second method can be applied both to a case in which the charge capture film ECF is formed from a polysilicon film and a case in which the charge capture film ECF is formed from a silicon nitride film.

For example, when the second method is applied to a configuration in which the charge capture film ECF is formed from a silicon nitride film, the charges are accumulated onto discrete trap levels in the silicon nitride film. In this state, the charges are accumulated intensively in a part of the silicon nitride film in the vicinity of the bottom corner of the trench TR. In this case, the longer the turning-on time of the LDMOSFET, the more the amount of charges are accumulated in the part of the silicon nitride film in the vicinity of the bottom corner of the trench TR. This facilitates the relaxing of the field intensity in the field concentration region in the vicinity of the bottom corner of the trench TR. Further, if there is an increase in the amount of charges accumulated in the part of the silicon nitride film in the vicinity of the bottom corner of the trench TR, the hot electrons generated due to the impact ionization are not likely to approach this part by the effect of Coulomb attraction. Thus, it is possible to suppress that the hot electrons travel along the side wall of the trench TR. As a result that the hot electrons are not likely to collide with the end part of the gate insulating film GOX, it is possible to suppress the decrease in the reliability of the gate insulating film GOX.

For example, when the second method is applied to a configuration in which the charge capture film ECF is formed from a polysilicon film, the charges are accumulated in a conduction band of the polysilicon film. Thus, the charges are diffused and accumulated entirely over the polysilicon film. In this case, the longer the turning-on period of the LDMOSFET, the more the amount of charges are accumulated entirely over the polysilicon film. This facilitates the relaxing of the field intensity of the field concentration region in the vicinity of the bottom corner of the trench TR. Further, if there is an increase in the amount of charges accumulated entirely over the polysilicon film, the hot electrons generated due to the impact ionization are not likely to approach the entire side wall of the trench TR, by the effect of Coulomb attraction. Thus, it is possible to suppress that the hot electrons travel along the side wall of the trench TR. As a result that the hot electrons are not likely to collide with the end part of the gate insulating film GOX, it is possible to suppress the decrease in the reliability of the gate insulating film GOX.

### <Modification 1>

Descriptions will now be made to a modification 1 of the LDMOSFET of this embodiment. FIG. 22 is a cross sectional view showing a schematic configuration of an LDMOSFET in a modification 1. In FIG. 22, in this modification 1, the charge capture film ECF is formed on a part of the side wall of the trench TR, instead of being formed entirely on the side wall of the trench TR. Particularly, in this modification 1, as illustrated in FIG. 22, the charge capture film ECF is formed in a part close to the side of the bottom corner of the trench TR, of the side wall of the trench TR. Even if the charge capture film ECF is configured in this manner, it is possible to accumulate the charges in the vicinity of the bottom corner of the trench TR. Therefore, it is possible to relax the field intensity of the field concentration region in the vicinity of the bottom corner of the trench TR.

The charge capture film ECF of the modification 1 can be formed by adjusting the amount of over-etching in the process of anisotropic etching illustrated in FIG. 13.

### <Modification 2>

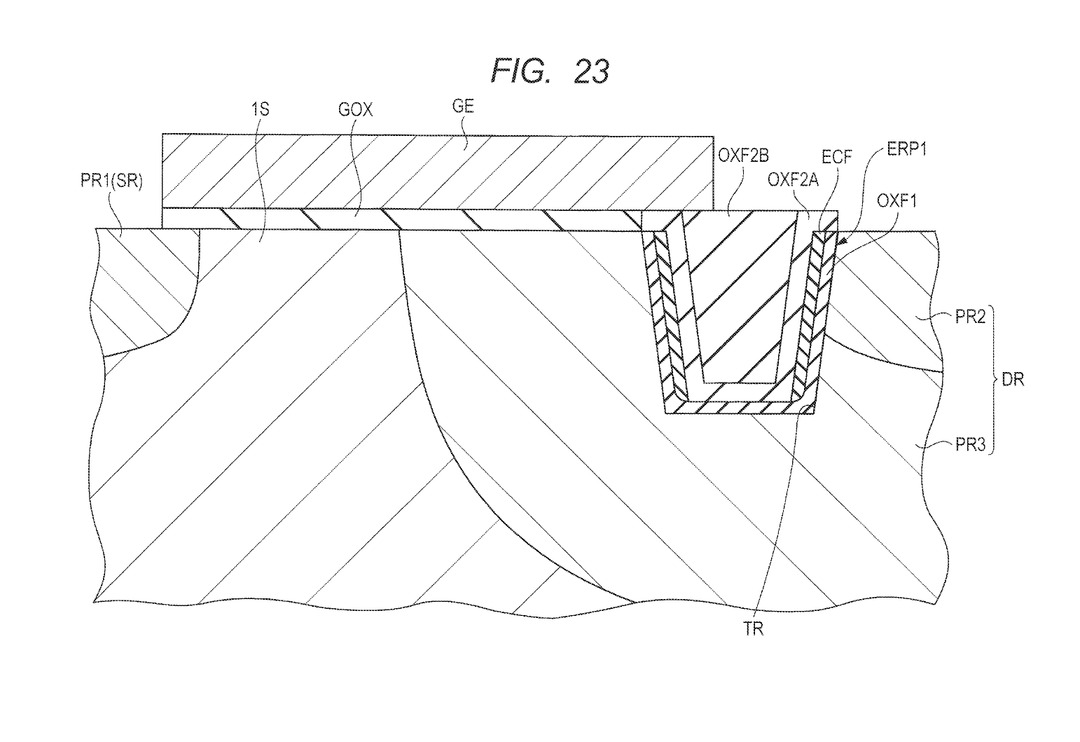

Descriptions will now be made to a modification 2 of an LDMOSFET of this embodiment. FIG. 23 is a cross sectional view showing a schematic configuration of the LDMOSFET in the modification 2. In the modification 2, the insulating film to be embedded in the trench TR is configured with an insulating film OXF2A in contact with the charge capture film ECF and an insulating film OXF2B in contact with the insulating film OXF2A. At this time, particularly, the feature point of the modification 2 is that the insulating film OXF2A is more densely formed (film having higher density) than the insulating film OXF2B. That is, the insulating film OXF2A in contact with the charge capture film ECF is more densely formed than the insulating film OXF2B. As a result, it is possible to suppress that the charges accumulated in the charge capture film ECF are leaked out. Accordingly, in the modification 2, the insulating film OXF2A in contact with the charge capture film ECF is more densely formed than the insulating film OXF2B, thereby improving the charge retention characteristic of the charge capture film ECF. As a result, it is possible to maintain the field relaxing effect by the charges accumulated in the charge capture film ECF, thereby improving the reliability of the semiconductor device including the LDMOSFET.

The insulating film OXF2A and the insulating film OXF2B can both be formed from a silicon oxide film. At this time, to form the insulating film OXF2A more densely formed than the insulating film OXF2B, the insulating film OXF2A is formed using a CVD method using TEOS as a raw material, and the insulating film OXF2B is formed using a high density plasma CVD method.

To form a dense film, if considered that the CVD method is preferably used using TEOS as a raw material, it can be considered that it is possible to form a film to be embedded in the trench TR using one kind of insulating film formed using the CVD method with TEOS as a raw material, as a film to be embedded in the trench TR, instead of forming both the insulating film OXF2A and the insulating film OXF2B manufactured in accordance with different manufacturing methods. However, in this case, in the CVD method using TEOS as a raw material, it is difficult that the embedding characteristic of the trench TR becomes preferable. In consideration of this, in the modification 2, the insulating film OXF2A in contact with the charge capture film ECF is formed using the CVD method using TEOS as a raw material for forming a dense film, while the insulating film OXF2B for filling the trench TR is formed using the high density plasma CVD method with excellent embedding characteristic. According to the modification 2, it is possible to attain a remarkable effect for improving the embedding characteristic of the trench TR, while improving the charge retention characteristic of the charge capture film ECF.

Accordingly, the descriptions have specifically been made to the inventions made by the present inventors, based on the preferred embodiments. However, the present invention is not limited to the above-described embodiments. Various changes may possibly be made without departing from the scope thereof.

What is claimed is:

1. A semiconductor device comprising:
a substrate;
a source region and a drain region which are separately formed in the substrate;
a field relaxing part which is contained in the drain region and formed in the substrate;
a gate insulating film which is provided over the substrate between the source region and the field relaxing part; and
a gate electrode which is formed over the gate insulating film;
wherein the field relaxing part has
a trench which is formed in the substrate,
a charge capture film which is formed on a side wall of the trench, and
an insulating film which is formed over the charge capture film and embedded in the trench.

2. The semiconductor device according to claim 1,
wherein the charge capture film is a film having a trap level for capturing en electron.

3. The semiconductor device according to claim 2,
wherein the charge capture film is a silicon nitride film.

4. The semiconductor device according to claim 1,
wherein the charge capture film is a polysilicon film.

5. The semiconductor device according to claim 1,
wherein the charge capture film is formed in a part of the side wall of the trench.

6. The semiconductor device according to claim 1,
wherein a silicon oxide film intervenes between the side wall of the trench and the charge capture film.

7. The semiconductor device according to claim 1,
wherein the insulating film has
a first insulating film in contact with the charge capture film, and
a second insulating film in contact with the first insulating film, and
wherein the first insulating film is more densely formed than the second insulating film.

8. The semiconductor device according to claim 1,
wherein the drain region has
a first semiconductor region which has a first impurity concentration, and
a second semiconductor region which has a second impurity concentration lower than the first impurity concentration and contains the first semiconductor region,
wherein the field relaxing part is in contact with the first semiconductor region and the second semiconductor region.

9. The semiconductor device according to claim 1,
wherein an electron is accumulated in the charge capture film.

10. The semiconductor device according to claim 1,
wherein each of the source region and the drain region is formed from a p-type semiconductor region.

11. A method for manufacturing a semiconductor device having
a substrate,
a source region and a drain region which are separately formed in the substrate,
a field relaxing part which is contained in the drain region and formed in the trench in the substrate,
a gate insulating film which is provided over the substrate between the source region and the field relaxing part, and
a gate electrode which is formed over the gate insulating film, the method comprising the steps of:
(a) preparing the substrate;
(b) forming the trench in the substrate;
(c) forming a first insulating film on an inner wall of the trench;
(d) forming a charge capture film in contact with the first insulating film, after the step (c);
(e) removing the charge capture film formed on a bottom part of the trench, by performing anisotropic etching for the charge capture film; and
(f) forming an embedded insulating film to be embedded in the trench, after the step (e).

12. The method for manufacturing the semiconductor device, according to claim 11,
wherein a plasma etching method is used in the step (e).

13. The method for manufacturing the semiconductor device, according to claim 11, further comprising the step of
performing plasma etching for a surface of the charge capture film, after the step (e) and before the step (f).

14. The method for manufacturing the semiconductor device, according to claim 11,
wherein the embedding insulating film has
a second insulating film in contact with the charge capture film, and
a third insulating film in contact with the second insulating film, and
wherein the step (f) includes the steps of
(f1) forming the second insulating film in contact with the charge capture film, and
(f2) forming the third insulating film in contact with the second insulating film, after the step (f1), and
wherein the second insulating film is more densely formed than the third insulating film.

15. The method for manufacturing the semiconductor device, according to claim 14,
wherein the second insulating film is a first silicon oxide film,
wherein the third insulating film is a second silicon oxide film,
wherein the step (f1) includes the step of forming the first silicon oxide film using a CVD method using TEOS as a raw material, and
wherein the step (f2) includes the step of forming the second silicon oxide film using a high density plasma CVD method.
